(19) United States
(12) Patent Application Publication
(10) Pub. No.: US 2024/0038773 A1
(43) Pub. Date: Feb. 1, 2024

(54) DISPLAY PANEL AND DISPLAY DEVICE

(71) Applicant: Wuhan China Star Optoelectronics Semiconductor Display Technology Co., Ltd., Wuhan (CN)

(72) Inventor: Yingchuan Jiang, Wuhan (CN)

(21) Appl. No.: 17/622,336

(22) PCT Filed: Dec. 14, 2021
(86) PCT No.: PCT/CN2021/137995

§ 371 Date: Dec. 23, 2021

(30) Foreign Application Priority Data
Nov. 30, 2021 (CN) 202111444426.2

(51) Int. Cl. H01L 27/12; H01L 25/16

(52) U.S. Cl. CPC H01L 27/124; H01L 27/1218; H01L 25/167; H01L 25/162

(57) ABSTRACT

A display panel and a display device are provided. The display panel includes a driving backplate and a plurality of display substrates. At least one first opening is defined in a first base and a first bonding terminals of the display substrates, the first opening penetrates the first base and the first bonding terminals, a bridging terminal is disposed in the first opening, the bridging terminal is electrically connected to a lateral surface of the first bonding terminals, so that a problem of poor connection between a display screen and a motherboard existing in current bezel-free splicing display technology is relieved.

### BACKGROUND OF INVENTION

### Field of Invention

The present application relates to a field of display technology and particularly to a display panel and a display device.

### Description of Prior Art

With continuous development of display technology, various applications of super-large display screens have become more and more extensive. The super-large display screens can satisfy requirements of people for long-distance viewing and larger information display. For cost considerations, the current super-large display screens are usually realized by splicing technology, i.e., a plurality of sub-displays are spliced together to form a super-large display screen. However, when the plurality of display screens are spliced together, large black splicing gaps can appear at splicing positions, which seriously affects display quality of the super-large display screens. In order to solve the black splicing gaps at the splicing positions, bezel-free splicing display technology has emerged, in which the plurality of display screens are spliced and are bonded to a motherboard. This technology requires bonding terminals to be disposed on each display screen and to be bonded to the motherboard. In order to achieve good contact between the display screens and the motherboard, laser drilling can be used to remove film layers under the bonding terminals to completely expose the bonding terminals. However, long-time laser drilling can damage the bonding terminals, resulting in poor connection between the display screens and the motherboard.

Therefore, a problem of poor connection between the display screens and the motherboard existing in current bezel-free splicing display technology needs to be solved.

### SUMMARY OF INVENTION

The present application provides a display panel and a display device to relieve the problem of poor connection between the display screens and the motherboard existing in current bezel-free splicing display technology.

In order to solve the problems mentioned above, the present disclosure provides the technical solutions as follows:

One embodiment of the present application provides, including a driving backplate and a display substrate electrically connected to the driving backplate. The display substrate includes:
a first base disposed facing toward the driving backplate; and
a plurality of first bonding terminals disposed on a side of the first base away from the driving backplate, wherein the display substrate is bonded to the driving backplate through the first bonding terminals to realize electrical connection, and
wherein, in bonding regions of the display substrate and the driving backplate, at least one first opening is defined in the first base and the first bonding terminals, the first opening penetrates the first base and the first bonding terminals, a bridging terminal is disposed in the first opening, the first bonding terminals are electrically connected to the driving backplate through the bridging terminal, and the bridging terminal is electrically connected to a lateral surface of the first bonding terminals.

In the display panel provided by one embodiment of the present application, the display substrate includes an auxiliary conductive layer disposed in the first opening, and the first bonding terminals are electrically connected to the bridging terminal through the auxiliary conductive layer.

In the display panel provided by one embodiment of the present application, the auxiliary conductive layer covers surfaces of the first base in the first opening and the first bonding terminals in the first opening.

In the display panel provided by one embodiment of the present application, a number of the first openings is plural.

In the display panel provided by one embodiment of the present application, the plurality of first openings are evenly arranged in the bonding region.

In the display panel provided by one embodiment of the present application, the display substrate further includes:
a first barrier layer covered on the first bonding terminals and the first base;
a driving circuit layer disposed on the first barrier layer and including a plurality of thin film transistors and a plurality of signal lines, the signal lines are electrically connected to the corresponding first bonding terminals;
a pixel electrode disposed on the driving circuit layer and electrically connected to the corresponding thin film transistor;
a pixel definition layer covered on the pixel electrode and the driving circuit layer, wherein the pixel definition layer has a second opening, and the second opening exposes a part of the pixel electrode.

In the display panel provided by one embodiment of the present application, the first opening further penetrates a part of the first barrier layer.

In the display panel provided by one embodiment of the present application, the pixel definition layer further has a third opening, and the third opening penetrates the pixel definition layer and the driving circuit layer.

In the display panel provided by one embodiment of the present application, a second bonding terminal is disposed on a side of the driving backplate facing toward the display substrate, and the second bonding terminal is electrically connected to the first bonding terminals.

In the display panel provided by one embodiment of the present application, a number of the display substrate is plural, and the plurality of display substrates are arranged in an array manner on the driving backplate.

One embodiment of the present application further provides a display device, which includes a housing and the display panel of one of the aforesaid embodiments. An accommodating chamber is formed in the housing. The display panel is disposed in the accommodating chamber.

In the display panel and the display device provided by the present application, the plurality of display substrates are arranged in an array manner on the driving backplate, each of the display substrates includes the first base and the plurality of first bonding terminals disposed on the first base, and the display substrate is bonded to the driving backplate through the first bonding terminals to realize electrical connection. In bonding regions of the display substrate and the driving backplate, at least one first opening is defined in the first base and the first bonding terminals, the first opening penetrates the first base and the first bonding terminals, a bridging terminal is disposed in the first opening, the first bonding terminals are electrically connected to the driving backplate through the bridging terminal, and the bridging terminal is electrically connected to a lateral surface of the first bonding terminals to reduce contact impedance of the first bonding terminals and the bridging terminal. Therefore, reliability of conduction between the display substrate and the driving backplate is improved, and the problem of poor connection between the display screens and the motherboard in the existing bezel-free splicing display technology is solved.

### DESCRIPTION OF DRAWINGS

In order to more clearly illustrate embodiments or the technical solutions of the present disclosure, the accompanying figures of the present disclosure required for illustrating embodiments or the technical solutions of the present disclosure will be described in brief. Obviously, the accompanying figures described below are only part of the embodiments of the present disclosure, from which those skilled in the art can derive further figures without making any inventive efforts.

FIG. 1 is a top view structural diagram of a display panel provided by one embodiment of the present application.

FIG. 2 is a schematic diagram of a partial sectional structure of the display panel provided by one embodiment of the present application.

FIG. 3 is a schematic diagram of a first partial sectional structure of a display substrate provided by one embodiment of the present application.

FIG. 4 is a schematic diagram of a second partial sectional structure of the display substrate provided by one embodiment of the present application.

FIG. 5 is a schematic diagram of a third partial sectional structure of the display panel provided by one embodiment of the present application.

FIG. 6 is a schematic diagram of a fourth partial sectional structure of the display panel provided by one embodiment of the present application.

FIG. 7 is a schematic diagram of a fifth partial sectional structure of the display panel provided by one embodiment of the present application.

FIG. 8 is a schematic diagram of a sixth partial sectional structure of the display panel provided by one embodiment of the present application.

FIG. 9 is a schematic diagram of a sectional structure of a display device provided by one embodiment of the present application.

### DETAILED DESCRIPTION OF EMBODIMENTS

The descriptions of embodiments below refer to accompanying drawings in order to illustrate certain embodiments which the present disclosure can implement. The directional terms of which the present application mentions, for example, “top,” “bottom,” “upper,” “lower,” “front,” “rear,” “left,” “right,” “inside,” “outside,” “side,” etc., are just refer to directions of the accompanying figures. Therefore, the used directional terms are for illustrating and understanding the present disclosure, but not for limiting the present disclosure. In the figures, units with similar structures are indicated by the same reference numerals. In the drawings, the thicknesses of layers and regions are exaggerated for clarity. The dimensions and thickness of each component shown in the accompanying figures are arbitrarily shown, present application is not limited thereto.

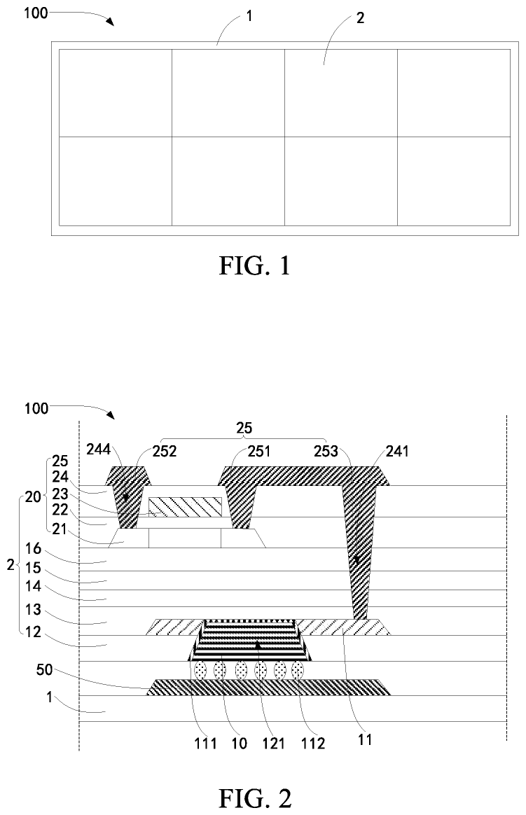

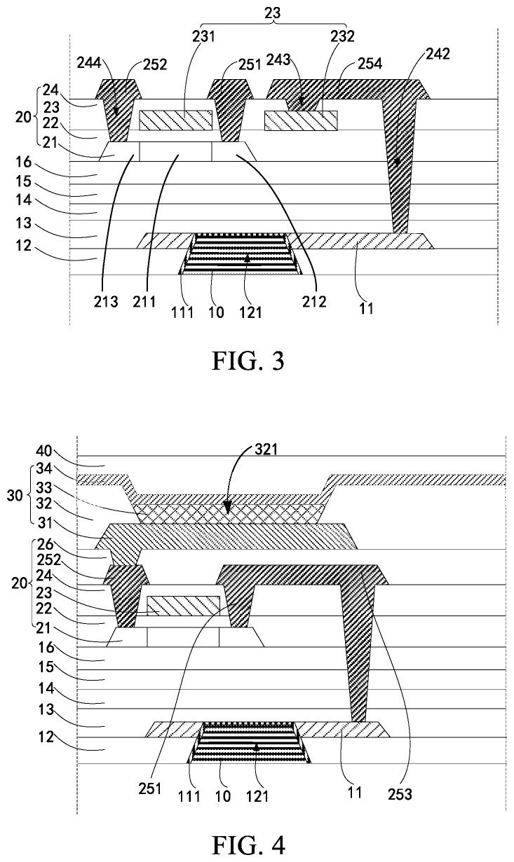

Please combine and refer to FIG. 1 and FIG. 4. FIG. 1 is a top view structural diagram of a display panel provided by one embodiment of the present application. FIG. 2 is a schematic diagram of a partial sectional structure of the display panel provided by one embodiment of the present application. FIG. 3 is a schematic diagram of a first sectional structure of a display substrate provided by one embodiment of the present disclosure. FIG. 4 is a schematic diagram of a second partial sectional structure of the display substrate provided by one embodiment of the present application. The display panel 100 includes a driving backplate 1 and a plurality of display substrates 2 arranged in an array manner on the driving backplate 1. Each of the display substrates 2 includes a first base facing toward the driving backplate 1, a plurality of first bonding terminals 11, and a first barrier layer 13. The plurality of first bonding terminals 11 are disposed on a side of the first base 12 away from the driving backplate 1. The first barrier layer 13 is covered on the first bonding terminals 11 and the first base 12. The display substrate 2 is bonded on the driving backplate 1 through the first bonding terminals 11 to realize electrical connection. Specifically, a second bonding terminal 50 is disposed on a position where the driving backplate 1 corresponds to the first bonding terminal 11 of each of the display substrates 2, and the second bonding terminal 50 is electrically connected to the first bonding terminals 11, thereby making the display substrate 2 to be electrically connected to the driving backplate 1.

In order to realize the electrical connection between the first bonding terminal 11 and the second bonding terminal 50, the first substrate 12 under the first bonding terminals 11 can be stripped off by a laser drilling method to expose the first bonding terminals 11 to facilitate electrical connection between the first bonding terminals 11 and the second bonding terminal 50. However, during laser drilling, due to fluctuation of laser energy itself and a surface flatness problem causing by thickness differences of materials of the first bonding terminal 11, it is difficult to control that only the first substrate 12 is removed without damaging the first bonding terminals 11 by only adjusting laser process parameters during laser drilling. If part of the first bonding terminals 11 is penetrated, conduction performance between the first bonding terminals 11 and the second bonding terminal 50 can be affected. The display panel 100 of the present application can solve the aforesaid problems caused by damage of the first bonding terminal 11.

Specifically, in bonding regions of the display substrate 2 and the driving backplate 1, at least one first opening 121 is defined in the first base 12 and the first bonding terminals 11, and the first opening 121 penetrates the first base 12 and the first bonding terminals 11 to expose the first barrier layer 13. A bridging terminal 10 is disposed in the first opening 121, the first bonding terminals 11 are electrically connected to the driving backplate 1 through the bridging terminal 10, and the bridging terminal 10 is electrically connected to a lateral surface of the first bonding terminal 11, which make the driving backplate 1 be electrically connected the display substrate 2 to prevent a problem of poor connection between the display screen and the motherboard caused by current bezel-free splicing display technology due to laser drilling. Wherein, the lateral surface of the first bonding terminal 11 refers to a cross section of the first bonding terminal 11 exposed by the first opening 121, and the electrical connection between the bridging terminal 10 and the lateral surface of the first bonding terminals 11 refers to conductive function realized by direct or indirect contact between the bridging terminal 10 and the lateral surface of the first bonding terminals 11.

Furthermore, in order to reduce the contact impedance between the first bonding terminals 11 and the bridging terminal 10 to improve the reliability of the conduction between the display substrate 2 and the driving backplate 1, when the bridging terminal 10 is electrically connected to a lateral surface of the first bonding terminal 11, the bridging terminal 10 and the lateral surface of the first bonding terminals 11 need to meet a certain contact area, i.e., it is necessary to satisfy that the bridging terminal 10 is in effective contact with the lateral surface of the first bonding terminals 11. Specifically, the effective contact between the bridging terminal 10 and the lateral surface of the first bonding terminal 11 refer to the area of the bridging terminal 10 directly or indirectly contacting to the lateral surface of the first bonding terminal 11 and being at least not less than a minimum area able to satisfy impedance requirement of the electrical connection between the bridging terminal 10 and the first bonding terminal 11.

The following will specifically explain how to make the bridge terminal 10 effectively contact to the lateral surface of the first bonding terminals 11.

Optionally, an orthogonal projection of the first opening 121 on the first bonding terminal 11 is in a range of the first bonding terminal 11, which makes a size of the first opening 121 be less than a size of the first bonding terminal 11. A shape of cross section of the first bonding terminal 11 includes a circular shape, a square, etc. When the cross section of the first bonding terminal 11 is circular, the size of the first bonding terminal 11 refers to a diameter of the first bonding terminal 11. When the cross section of the first bonding terminal 11 is square, the size of the first bonding terminal 11 refers to an edge length of the first bonding terminal 11. Definition of a size of the first opening 121 is same as that of the first bonding terminal 11, which specifically depends on a cross-sectional shape of the first opening 121. The cross-sectional shape of the first opening 121 relates to the cross-sectional shape of the first bonding terminal 11.

Specifically, the cross-sectional shape of the first opening 121 also includes a circular shape, or a square shape, etc. When the cross-sectional shape of the first opening 121 is circular, the size of the first opening 121 refers to a diameter of the first opening 121. When the cross-sectional of the first opening 121 is square, the size of the first opening 121 refers to an edge length of the first opening 121. It can be understood that when the cross-sectional shape of the first opening 121 is circular, an inner surface of the first opening 121 is smooth. Therefore, when a conductive material is filled in the first opening 121 to form the bridge terminal 10, manufacture of the bridge terminal 10 is more conducive.

Furthermore, the first bonding terminals 11 are electrically connected to the second bonding terminal 50 through the bridging terminal 10. Of course, optionally, an auxiliary bridge layer 112 can be further disposed between the bridging terminal 10 and the second bonding terminal 50, so that the bridge terminal 10 and the second bonding terminal 50 are allowed to be in good contact. Wherein, the first bonding terminal 11 and the second bonding terminal 50 can be made of a metal or alloy with strong oxidation resistance and low resistivity, such as MO, Al alloy, etc., to ensure stability of the first bonding terminal 11. The bridging terminal 10 can be formed by filling conductive silver paste in the first opening 121, and the auxiliary bridging layer 112 can be made of conductive glue or metal to ensure connection reliability of the first bonding terminal 11 and the second bonding terminal 50.

Optionally, in order to make the bridging terminal 10 effectively contact the lateral surface of the first bonding terminal 11, an auxiliary conductive layer 111 can be disposed in the first opening 121, and the material of the auxiliary conductive layer 111 can be same as a material of the first bonding terminal 11. Manner of disposing the auxiliary conductive layer 111 includes using an evaporation deposition process, etc. The auxiliary conductive layer 111 at least covers the first bonding terminals 11 in the first opening 121 and the first barrier layer 13 exposed by the first opening 121, or the auxiliary conductive layer 111 can also at least covers the first bonding terminals 11 in the first opening 121 and the first base 12 in the first opening 121. Of course, the auxiliary conductive layer 111 can further cover the first bonding terminals 11 and the first base 12 in the first opening 121, and the exposed first barrier layer 13.

The bridging terminal 10 is filled in the first opening 121 and contacts to the auxiliary conductive layer 111, and the auxiliary conductive layer 111 is evaporated and deposited in the first opening 121, which is equivalent to be integrated with the first bonding terminal 11 in one piece. Therefore, electric connection of the bridging terminal 10 and the lateral surface of the first bonding terminal 11 is realized through indirect contact, and an effective contact area of the bridging terminal 10 and the lateral surface of the first bonding terminal 11 is greatly increased. Wherein, the effective contact area of the bridging terminal 10 and the lateral surface of the first bonding terminal 11 refers to a contact area of the bridging terminal 10 and the auxiliary conductive layer 111.

By the effective contact area of the bridging terminal 10 and the lateral surface of the first bonding terminal 11, impedance between the bridging terminal 10 and the first bonding terminal 11 can be able to decrease, and conductivity of the first bonding terminal 11 and the second bonding terminal 50 is increased, thereby increasing stability of bonding of the display substrate 2 and the drive backplate 1.

The driving backplate 1 is bonded to the display substrate 2 for providing various driving signals to the display substrate 2. Specifically, a driving chip (not shown in the figure) is further disposed on the driving backplate 1, and the second bonding terminal 50 is electrically connected to the driving chip to transmit a driving signal of the driving chip to the corresponding display substrate 2 through the first bonding terminal 11. Therefore, by disposing peripheral circuits such as the driver chip, etc. on the driver backplate 1, and by disposing the first bonding terminal 11 on every display substrate 2, the signal lines in the display substrate 2 are made to be electrically connected to the first bonding terminal 11 and are connected to the driving chip through the corresponding second bonding terminal 50 to realize signal transmission. Therefore, there is not need to reserve a bezel region on each of the display substrates 2 to dispose the driver chip and various bonding wirings, so that after a plurality of the display substrates 2 are spliced, no large splicing gap can exist between the adjacent display substrates 2.

The film structures of the display substrate 2 are described in detail as follow.

Optionally, the display substrates 2 further include a second substrate 14, a second barrier layer 15, a buffer layer 16, a driving circuit layer a pixel electrode 31, and a pixel definition layer 32 sequentially stacked on the first barrier layer 13. The first barrier layer 13, the second barrier layer 15 and the buffer layer 16 can be formed of inorganic materials such as silicon oxide (SiOx), silicon nitride (SiNx), silicon oxynitride (SiON), etc., to prevent undesired impurities or contaminants (such as moisture, oxygen, etc.) from diffusing into devices that may be damaged by these impurities or contaminants from the first substrate 12 and the second substrate 14. Furthermore, the materials of the first substrate 12 and the second substrate 14 include flexible film materials such as polyimide (PI). Meanwhile, an buffer layer 16 can also provide a flat top surface to facilitate manufacturing other film structures on the buffer layer 16. Of course, the display substrate 2 of the present application is not limited thereto. The display substrate 2 of the present application can include more or less substrate film layers and barrier film layers.

The driving circuit layer 20 is disposed on the first barrier layer 13, more specifically, the driving circuit layer 20 is disposed on the buffer layer 16. The driving circuit layer 20 includes a plurality of thin film transistors and a plurality of signal lines, and the signal lines are electrically connected to the corresponding first bonding terminal 11.

Optionally, the driving circuit layer 20 includes a semiconductor layer 21, a gate insulation layer 22, a gate layer 23, an interlayer insulation layer 24, and a source-drain layer 25. The semiconductor layer 21 is disposed on the buffer layer 16, and the semiconductor layer 21 includes a channel region 211, and a source electrode region 212 and a drain electrode region 213 located on two opposite sides of the channel region 211. The gate insulation layer 22 is covered on the semiconductor layer 21 and the buffer layer 16. The gate layer 23 is disposed on the gate insulation layer 22. Other signal lines such as a gate electrode 231 and gate scanning lines 232 are formed by patterning the gate layer 23. The gate electrode 231 is disposed corresponding to the channel region 211 of the semiconductor layer 21. The gate scanning lines 232 are electrically connected to the corresponding first bonding terminals 11. The interlayer insulation layer 24 is covered on the gate electrode layer 23 and the gate insulation layer 22. The source-drain electrode layer 25 is disposed on the interlayer insulation layer 24. Other signal lines such as a source electrode 251, a drain electrode 252, and data lines 253, etc. are formed of patterning the source-drain layer 25. The source electrode 251 and the drain electrode 252 are respectively electrically connected to a source region 212 and a drain region 213 of the corresponding semiconductor layer 21. The data lines 253 are electrically connected to the corresponding first bonding terminal 11. Wherein, the plurality of signal lines of the driving circuit layer 20 include the gate scanning lines 232 and the data lines 253. Different signal wires are electrically connected to different first bonding terminals 11. Wherein, the thin film transistor includes the semiconductor layer 21, the gate electrode 231, the source electrode 251, and the drain electrode 252.

Specifically, the interlayer insulation layer 24 is patterned to form a first via hole 241. The first via hole 241 penetrates the interlayer insulation layer 24, the gate insulation layer 22, the buffer layer 16, the second barrier layer 15, the second substrate 14, and the first barrier layer 13, until to the first bonding terminal 11, to expose a part of the first bonding terminal 11. The data line 253 is electrically connected to the first bonding terminal 11 through the first via hole 241, while the data line 253 is also electrically connected to the source electrode 251 or the drain electrode 252 at the same time. In the present application, the data line 253 being electrically connected to the source electrode 251 is taken as an example.

Furthermore, as illustrated in FIG. 3, the interlayer insulation layer 24 is patterned to further form a second via hole 242 and a third via hole 243. The second via hole 242 is same as a structure of the first via hole 241, i.e. the second via hole 242 also penetrates the interlayer insulation layer 24, the gate insulation layer 22, the buffer layer 16, the second barrier layer 15, the second substrate 14, and the first barrier layer 13, until to the first bonding terminal 11, to expose a part of the first bonding terminal 11. The third via hole 243 penetrates the interlayer insulation layer 24 to the gate scanning line 232 to expose a part of the gate scanning line 232. The source-drain layer 25 further includes a signal transfer line 254 disposed on a same layer as the data line 253. The signal transfer line 254 is electrically connected to the first bonding terminal 11 and the gate scanning line 232 through the second via hole 242 and the third via hole 243, so that the gate scanning line 232 is electrically connected to the first bonding terminal 11. It can be understood that the gate scanning line 232 and the data line 253 are respectively connected to different first bonding terminals 11.

Furthermore, the interlayer insulation layer 24 is patterned to further form a plurality of fifth via holes 244. The plurality of fifth via holes 244 penetrate the interlayer insulation layer 24 and the gate insulation layer 22 to expose the source electrode region 212 and the drain electrode region 213 respectively. The source electrode 251 is electrically connected to the source electrode region 212 through one of the fifth via holes 244. The drain electrode 252 is electrically connected to the drain electrode region 213 through another fifth via hole 244.

It should be noted that “disposing on a same layer” in the present application refers to a film layer formed of a same material is patterned to obtain at least two different features in manufacturing processes, so the at least two different features are disposed in the same layer. For example, in this embodiment, the signal transfer line 254 and the data line 253 are obtained by patterning a same conductive film layer, so the signal transfer line 254 and the data line 253 are disposed on a same layer.

In addition, the plurality of signal lines of the driving circuit layer 20 in the present application are not limited to the data line 253 and the gate scanning line 232. The plurality of signal lines can also include source voltage (VSS), drain voltage (VDD) power supply lines, and other various signal lines for display or non-display, and the different signal wires are electrically connected to the different first bonding terminals 11 to obtain different signals. For example, the data line 253 is electrically connected to the corresponding first bonding terminal 11 to obtain a source driving signal and provide the source driving signal to the source electrode 251, and the gate scanning line 232 is electrically connected to the corresponding first bonding terminal 11 to obtain a gate scanning signal and provide the gate scanning signal to the gate electrode 231.

Meanwhile, in order to provide a flat surface for the driving circuit layer 20, the driving circuit layer 20 further includes a planarization layer 26 covering the source-drain layer 25 and the interlayer insulation layer 24. Of course, the structure of the driving circuit layer 20 of the present application is not limited to that illustrated in this embodiment. The driving circuit layer 20 of the present application can also include more or fewer film layers, and positional relations of each film layer is not limited to that illustrated in this embodiment. For example, a double-gate structure can also be adopted in the gate electrode layer 23 of the present application, and the gate electrode layer 23 can also be located under the semiconductor layer 21 to form a bottom-gate structure.

It can be understood, as illustrated in FIG. 4, in order to realize a display function of the display substrate 2, the display substrate 2 further includes a light-emitting functional layer 30 disposed on the driving circuit layer 20. The driving circuit layer 20 is configured to provide a driving voltage to the light-emitting functional layer 30 to make the light-emitting functional layer 30 emit light. Furthermore, in order to protect reliability of the light-emitting functional layer 30 and prevent intrusion of water and oxygen from causing the light-emitting functional layer 30 to fail, and the display substrate 2 further includes an encapsulation layer 40.

Specifically, the light-emitting functional layer 30 includes a pixel electrode 31, a pixel definition layer 32, a light-emitting unit 33, and a cathode 34. The pixel electrode 31 is disposed on the driving circuit layer 20 and is electrically connected to the corresponding thin film transistor. The pixel definition layer 32 is covered on the pixel electrode 31 and the driving circuit layer 20. The pixel definition layer 32 has a second opening 321. The second opening 321 exposes a part of the pixel electrode 31.

More specifically, the pixel electrode 31 is disposed on the planarization layer 26 and is electrically connected to the source electrode 251 or the drain electrode 252 through a via hole of the planarization layer 26. Of course, because the electrical connection of the data line 253 and the source electrode 251 is taken as an example in this embodiment, the electrical connection of the pixel electrode 31 and the drain electrode 252 is taken as an example in this embodiment correspondingly. The pixel definition layer 32 is covered on the pixel electrode 31 and the planarization layer 26, and the pixel definition layer 32 is patterned to form the second opening 321. The second opening 321 exposes a part of the pixel electrode 31 to define a region where the light-emitting units 33 are disposed.

The light-emitting units 33 are formed of light-emitting materials printed or evaporated in the second opening 321 of the pixel definition layer 32, and different colors of light-emitting materials form different colors of light-emitting units 33. For example, the light-emitting units 33 can include red light-emitting units formed by a red light-emitting material, green light-emitting units formed by a green light-emitting material, and blue light-emitting units formed by a blue light-emitting material. The red light-emitting unit emits red light, the green light-emitting unit emits green light, and the blue light-emitting unit emits blue light.

The cathode 34 covers the light-emitting units 33 and the pixel definition layer 32. The light-emitting units 33 emit light under combined action of the pixel electrode 31 and the cathode 34. The light-emitting units 33 of different colors emit lights of different colors, thereby realizing display of pixels of the display substrate 2.

Optionally, the pixel electrode 31 can be a transparent electrode or a reflective electrode. If the pixel electrode 31 is a transparent electrode, the pixel electrode 31 can be made of, for example, indium tin oxide (ITO), indium zinc oxide (IZO), ZnO, or In₂O₃. If the pixel electrode 31 is a reflective electrode, the pixel electrode 31 can include, for example, a reflective layer formed of Ag, Mg, Al, Pt, Pd, Au, Ni, Nd, Ir, Cr, or a combination thereof, or a reflective layer formed of ITO, IZO, ZnO, or In₂O₃. However, the pixel electrode 31 is not limited thereto. The pixel electrode 31 can be formed of various materials, and they can also be formed into a single-layer or a multi-layer structure.

It should be noted that whether the transparent electrode or the reflective electrode is adopted on the pixel electrode 31 depends on a light-emitting direction of the display panel 100. When top emission is adopted in the display panel 100, the pixel electrode 31 can be a transparent electrode or a reflective electrode. Of course, an utilization rate of light emitted by the light-emitting units 33 can be improved when the reflective electrode is used. When bottom emission is adopted in the display panel 100, the transparent electrode is adopted in the pixel electrode 31 to improve a light transmittance rate. In this embodiment, top emission adopted in the display panel 100 is taken as an example. Therefore, in order to increase the light transmittance rate, the cathode 34 needs to be formed of a transparent conductive material. For example, the cathode 34 can be formed of transparent conductive oxides, such as ITO, IZO, ZnO or In₂O₃, etc.

Optionally, the light-emitting functional layer 30 can further include a hole injection layer (HIL) and a hole transport layer (HTL) disposed between the light-emitting units 33 and the pixel electrode 31, and an electron injection layer (EIL) and an electron transport layer (ETL) disposed between the light-emitting units 33 and the cathode 34. The hole injection layer receives the holes transmitted by the pixel electrode 31 The holes are transmitted to the light-emitting units 33 through the hole transport layer. The electron injection layer receives the electrons transmitted by the cathode 34. The electrons are transmitted to the light-emitting unit 33 through the electron transport layer. The holes and the electrons combine at positions of the light-emitting units 33 to generate excitons, and the excitons transition from an excited state to a ground state to release energy and emit light.

The encapsulation layer 40 covers the light-emitting functional layer 30, and is used to protect the light-emitting units 33 of the light-emitting functional layer 30 to prevent intrusion of water and oxygen from causing the light-emitting unit 33 to fail. Optionally, the encapsulation layer 40 can be encapsulated by a thin film. For example, the encapsulation layer 40 can be a laminated structure formed by sequentially stacking three layers of films of a first inorganic encapsulation layer, an organic encapsulation layer, and a second inorganic encapsulation layer, or a laminated structure with more stacked layers.

In this embodiment, the display panel 100 includes a driving backplate 1 and a plurality of display substrates 2 arranged in an array manner on the driving backplate 1, i.e., the plurality of the display substrates 2 are spliced with each other and bonded on the driving backplate 1. The plurality of signal lines of each of the display substrates 2 are electrically connected to the driving backplate 1 through different first bonding terminals 11. Specifically, a second bonding terminal 50 is disposed on a position where the driving backplate 1 corresponds to the first bonding terminal 11 of each of the display substrates 2, and the second bonding terminal 50 is electrically connected to the first bonding terminals 11, thereby making the display substrate 2 to be electrically connected to the driving backplate 1.

Meanwhile, the first opening 121 is defined in the bonding region of the first bonding terminal 11 and the second bonding terminal 50, and the auxiliary conductive layer 111 is disposed in the first opening 121. The bridging terminal 10 is filled in the first opening 121 and contacts to the auxiliary conductive layer 111, which makes the effective contact area of the bridge terminal 10 and the first bonding terminal 11 be greatly improved, thereby being able to reduce the impedance between the bridging terminal 10 and the first bonding terminal 11, improving conductivity of the first bonding terminal 11 and the second bonding terminal 50. and the display substrate can be improved. 2 Therefore, stability of the display substrates 2 bonding to the driving backplate 1 can be improved, thereby solving the problem of poor connection between the display and the motherboard in the current bezel-free splicing display technology.

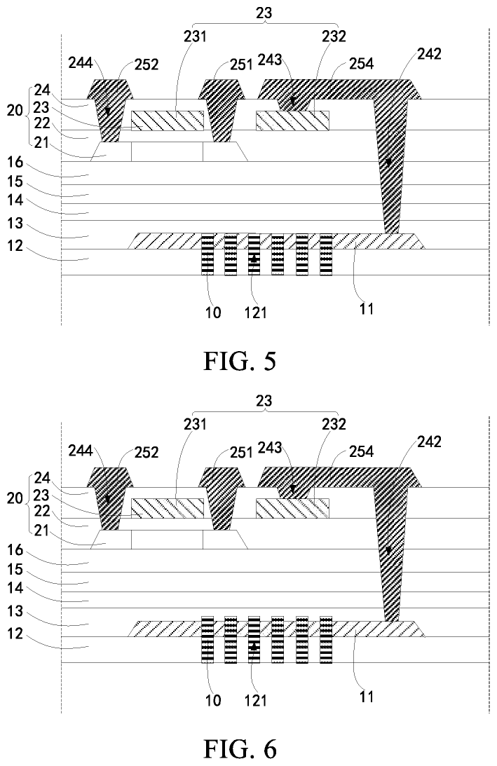

In one embodiment, please refer and combine FIG. 1 to FIG. 5. FIG. 5 is a schematic diagram of a third partial sectional structure of the display panel provided by one embodiment of the present application. The difference from the aforesaid embodiment is that a number of the first openings 121 is plural, and each of the first openings 121 is provided with the bridging terminal 10, so a number of the bridging terminals 10 is also plural. Optionally, sizes of the plurality of first openings 121 are same, and the plurality of first openings 121 are evenly arranged in the bonding region.

Specifically, when the thickness of the first bonding terminal 11 is relatively thin, the contact area between the bridge terminal 10 and the first bonding terminal 11 cannot satisfy impedance requirement of electrical connection between the bridge terminal 10 and the first bonding terminal 11. At this time, by defining the plurality of the first openings 121 in the bonding region, the auxiliary conductive layer 111 does not need to be evaporated and deposited in the first openings 121, the effective contact area of the bridging terminal 10 and the lateral surface of the first bonding terminal 11 can also be satisfied, thereby satisfying the impedance requirement of the electrical connection of the bridge terminal 10 and the first bonding terminal 11. Wherein, regarding to this embodiment, the effective contact area of the bridging terminal 10 and the lateral surface of the first bonding terminal 11 refers to a sum of areas where the bridging terminal 10 directly contacts to the lateral surface of the first bonding terminal 11 in each of the first openings 121.

In the following, the thickness of the first bonding terminal 11 being h and the bonding region being a square area with a edge length of 100 micrometers are taken as an example to describe that disposing the plurality of the first openings 121 can satisfy a principle of the impedance requirement of electrical connection of the bridging terminal 10 and between the first bonding terminals 11. When an opening is defined in a square bonding region with an edge length of 100 μm, the contact area between of bridging terminal and the first bonding terminal S1=100*h*4=400 hum². When the plurality of first openings 121 are defined in the square bonding region with the edge length of 100 μm, for example, 25 square first openings 121 with the edge length of 10 μm can be defined. A hole interval between the plurality of first openings 121 is 10 μm, and the effective contact area of the bridging terminal 10 and the first bonding terminal S2=10*h*4*25=1000 hum². It can be understood that by disposing the plurality of the first openings 121 in the bonding regions having same area, the effective contact area of the bridging terminal 10 and the lateral surface of the first bonding terminal 11 can be increased. Therefore, impedance between the bridging terminal 10 and the first bonding terminal 11 can be able to decrease, and conductivity of the first bonding terminal 11 and the second bonding terminal 50 is increased, thereby increasing stability of bonding of the display substrate 2 and the drive backplate 1.

In addition, it should be noted that, in this embodiment, the auxiliary conductive layer 111 can also be evaporated and deposited in each of the first openings 121, which can further increase the effective contact area of the bridging terminal 10 and the lateral surface of the first bonding terminal 11. The impedance requirement of the electrical connection between the bridging terminal 10 and the first bonding terminal 11 can be satisfied more. For other descriptions, please refer to the embodiments mentioned above, and redundant description will not be mentioned herein again.

In one embodiment, please refer to FIG. 6. FIG. 6 is a schematic diagram of a fourth partial sectional structure of the display panel provided by one embodiment of the present application. The difference from the aforesaid embodiment is that the first opening 121 further penetrates part of the first barrier layer 13 to ensure that the bridging terminal 10 is in full contact with the first bonding terminal 11. For other descriptions, please refer to the embodiments mentioned above, and redundant description will not be mentioned herein again.

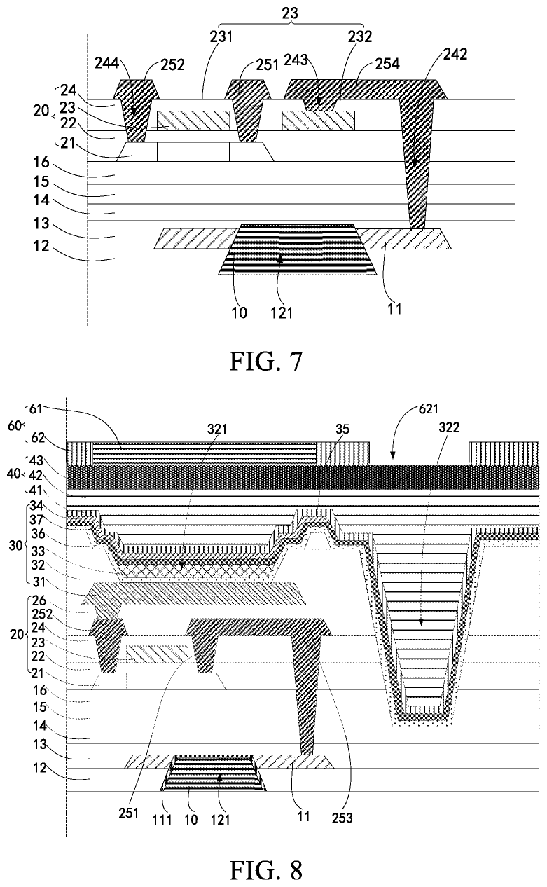

In one embodiment, please refer to FIG. 7. FIG. 7 is a schematic diagram of a fifth partial sectional structure of the display panel provided by one embodiment of the present application. The difference from the aforesaid embodiment is that the thickness of the first bonding terminal 11 is relatively thick. At this time, a conductive material with low resistivity can be directly filled in the first opening 121 to form the bridging terminal 10. In this way, effective contact of the bridging terminal 10 and the lateral surface of the first bonding terminal 11 can also be realized. In this way, the effective contact area of the bridging terminal 10 and the lateral surface of the first bonding terminal 11 is a direct contact area of the bridging terminal 10 and the lateral surface of the first bonding terminal 11. Therefore, by using the conductive material with the low resistivity to form the bridging terminal, while effective contact of the bridge terminal 10 and the lateral surface of the first bonding terminal 11 is satisfied, the impedance between the bridging terminal 10 and the first bonding terminal 11 can be further reduced, and conductivity of the first bonding terminal 11 and the second bonding terminal 50 is improved, thereby improving stability of the display substrate 2 bonding to the driving backplate 1. For other descriptions, please refer to the embodiments mentioned above, and redundant description will not be mentioned herein again.

In one embodiment, please refer to FIG. 8. FIG. 8 is a schematic diagram of a sixth partial sectional structure of the display panel provided by one embodiment of the present application. The difference from the aforesaid embodiment is that the pixel definition layer 32 further has a third opening 322, the third opening 322 penetrates the pixel definition layer 32 and the driving circuit layer 20, and the encapsulation layer 40 is filled in the third opening 322 to increase the transmittance rate of this region and realize transparent display.

Specifically, the third opening 322 penetrates the pixel definition layer 32 and film layers such as the planarization layer 26, the interlayer insulation layer 24, and the gate insulating layer 22 on the driving circuit layer 20. Of course, the third opening 322 can also penetrate inorganic film layers such as the buffer layer 16 and the second barrier layer 15 to further increase the transmittance rate of the display panel 100 in this region. A first inorganic encapsulation layer 41 in the encapsulation layer 40 covers a hole wall of the third opening 322. The organic encapsulation layer 42 is filled in the third opening 322. The second inorganic encapsulation layer 43 covers the organic encapsulation layer 42. In addition, a retaining wall 35 is also disposed on the pixel definition layer 32, and the retaining wall 35 is configured to block overflow.

Optionally, when the light-emitting functional layer 30 further includes the hole transport layer 36, the hole transport layer 36 is also evaporated and deposited in the third opening 322. At this time, the first inorganic encapsulation layer 41 covers the hole transport layer 36 in the third opening 322.

Optionally, the light-emitting functional layer 30 can further include a light extraction layer 37. The light extraction layer 37 is disposed between the light-emitting units 33 and the cathode 34 for improving light extraction efficiency of the light-emitting units 33. At this time, the light extraction layer 37 is also disposed in the third opening 322, so in the third opening 322, the light extraction layer 37 covers on the hole transport layer 36, and the first inorganic encapsulation layer 41 covers on the light extraction layer 37.

Further, the display substrate 2 further includes a color filter 60 disposed on the encapsulation layer 40, which is used to replace a conventional polarizer to reduce the thickness of the display substrate 2. The color filter 60 includes a plurality of color films 61 and a light shielding layer 62 located between each of the color films 61. The color films 61 include red color films, green color films, and blue color films. Wherein, the red color films correspond to the red light-emitting units, the green color film correspond to the green light-emitting units, and the blue color films correspond to the blue light-emitting units. Furthermore, in order to improve a transmittance rate of a region of the third opening 322, a fourth opening 621 is defined at a position where the light shielding layer 62 corresponds to the third opening 322. For other descriptions, please refer to the embodiments mentioned above, and redundant description will not be mentioned herein again.

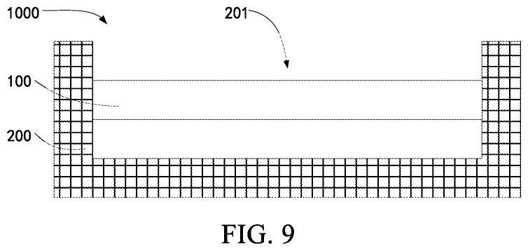

In one embodiment, please refer to FIG. 9. FIG. 9 is a schematic diagram of a sectional structure of a display device provided by one embodiment of the present application. The display device 1000 includes a housing 200 and the display panel 100 of one of the aforesaid embodiments. An accommodating chamber 100 is formed in the housing 200. The display panel 100 is disposed in the accommodating chamber 201.

According to embodiments mentioned above:

The present application provides a display panel and a display device. The display panel includes a driving backplate and a plurality of display substrates arranged in an array manner on the driving backplate. Each of the display substrates includes the first base and the plurality of first bonding terminals disposed on the first base. The display substrate is bonded to the driving backplate through the first bonding terminals to realize electrical connection. In bonding regions of the display substrate and the driving backplate, at least one first opening is defined in the first base and the first bonding terminals, the first opening penetrates the first base and the first bonding terminals, a bridging terminal is disposed in the first opening, the first bonding terminals are electrically connected to the driving backplate through the bridging terminal, the bridging terminal is electrically connected to a lateral surface of the first bonding terminals to reduce contact impedance of the first bonding terminals and the bridging terminal. Therefore, reliability of conduction between the display substrate and the driving backplate is improved, and the problem of poor connection between the display screens and the motherboard in the existing bezel-free splicing display technology is solved.

In the above embodiments, the description of each embodiment has its emphasis, and for some embodiments that may not be detailed, reference may be made to the relevant description of other embodiments.

The embodiments of present disclosure are described in detail above. This article uses specific cases for describing the principles and the embodiments of the present disclosure, and the description of the embodiments mentioned above is only for helping to understand the method and the core idea of the present disclosure. It should be understood by those skilled in the art, that it can perform changes in the technical solution of the embodiments mentioned above, or can perform equivalent replacements in part of technical characteristics, and the changes or replacements do not make the essence of the corresponding technical solution depart from the scope of the technical solution of each embodiment of the present disclosure.

What is claimed is:

1. A display panel, comprising a driving backplate and a display substrate electrically connected to the driving backplate, wherein the display substrate comprises:
a first base disposed facing toward the driving backplate; and
a plurality of first bonding terminals disposed on a side of the first base away from the driving backplate, wherein the display substrate is bonded to the driving backplate through the first bonding terminals to realize electrical connection,
wherein, in bonding regions of the display substrate and the driving backplate, at least one first opening is defined in the first base and the first bonding terminals, the first opening penetrates the first base and the first bonding terminals, a bridging terminal is disposed in the first opening, the first bonding terminals are electrically connected to the driving backplate through the bridging terminal, and the bridging terminal is electrically connected to a lateral surface of the first bonding terminals.

2. The display panel as claimed in claim 1, wherein the display substrate comprises an auxiliary conductive layer disposed in the first opening, and the first bonding terminals are electrically connected to the bridging terminal through the auxiliary conductive layer.

3. The display panel as claimed in claim 2, wherein the auxiliary conductive layer covers surfaces of the first base in the first opening and the first bonding terminals in the first opening.

4. The display panel as claimed in claim 1, wherein a number of the first openings is plural.

5. The display panel as claimed in claim 4, wherein the plurality of first openings are evenly arranged in the bonding region.

6. The display panel as claimed in claim 5, wherein the display substrate comprises:
a first barrier layer covered on the first bonding terminals and the first base;
a driving circuit layer disposed on the first barrier layer and comprising a plurality of thin film transistors and a plurality of signal lines, the signal lines are electrically connected to the corresponding first bonding terminals;
a pixel electrode disposed on the driving circuit layer and electrically connected to the corresponding thin film transistor;
a pixel definition layer covered on the pixel electrode and the driving circuit layer, wherein the pixel definition layer has a second opening, and the second opening exposes a part of the pixel electrode.

7. The display panel as claimed in claim 6, wherein the first opening penetrates a part of the first barrier layer.

8. The display panel as claimed in claim 6, wherein the pixel definition layer has a third opening, and the third opening penetrates the pixel definition layer and the driving circuit layer.

9. The display panel as claimed in claim 1, wherein a second bonding terminal is disposed on a side of the driving backplate facing toward the display substrate, and the second bonding terminal is electrically connected to the first bonding terminals.

10. The display panel as claimed in claim 9, wherein a number of the display substrate is plural, and the plurality of display substrates are arranged in an array manner on the driving backplate.

11. A display device, comprising a housing and a display panel, wherein an accommodating chamber is defined in the housing, the display panel is disposed in the accommodating chamber, wherein the display panel comprises a driving backplate and a display substrate electrically connected to the driving backplate, the display substrate comprises:
a first base disposed facing toward the driving backplate; and
a plurality of first bonding terminals disposed on a side of the first base away from the driving backplate, wherein the display substrate is bonded to the driving backplate through the first bonding terminals to realize electrical connection, and
wherein, in bonding regions of the display substrate and the driving backplate, at least one first opening is defined in the first base and the first bonding terminals, the first opening penetrates the first base and the first bonding terminals, a bridging terminal is disposed in the first opening, the first bonding terminals are electrically connected to the driving backplate through the bridging terminal, and the bridging terminal is electrically connected to a lateral surface of the first bonding terminals.

12. The display device as claimed in claim 11, wherein the display substrate comprises an auxiliary conductive layer disposed in the first opening, and the first bonding terminals are electrically connected to the bridging terminal through the auxiliary conductive layer.

13. The display device as claimed in claim 12, wherein the auxiliary conductive layer covers surfaces of the first base in the first opening and the first bonding terminals in the first opening.

14. The display device as claimed in claim 11, wherein a number of the first openings is plural.

15. The display device as claimed in claim 14, wherein the plurality of first openings are evenly arranged in the bonding region.

16. The display device as claimed in claim 15, wherein the display substrate comprises:
a first barrier layer covered on the first bonding terminals and the first base;
a driving circuit layer disposed on the first barrier layer and comprising a plurality of thin film transistors and a plurality of signal lines, the signal lines are electrically connected to the corresponding first bonding terminals;
a pixel electrode disposed on the driving circuit layer and electrically connected to the corresponding thin film transistor;
a pixel definition layer covered on the pixel electrode and the driving circuit layer, the second opening exposes a part of the pixel electrode.

17. The display device as claimed in claim 16, wherein the first opening penetrates a part of the first barrier layer.

18. The display device as claimed in claim 16, wherein the pixel definition layer has a third opening, and the third opening penetrates the pixel definition layer and the driving circuit layer.

19. The display device as claimed in claim 11, wherein a second bonding terminal is disposed on a side of the driving backplate facing toward the display substrate, and the second bonding terminal is electrically connected to the first bonding terminals.

20. The display device as claimed in claim 19, wherein a number of the display substrate is plural, and the plurality of display substrates are arranged in an array manner on the driving backplate.
